(19) United States
(12) Patent Application Publication
(10) Pub. No.: US 2017/0365732 A1
(43) Pub. Date: Dec. 21, 2017

(54) DILUTE NITRIDE BISMIDE SEMICONDUCTOR ALLOYS

(71) Applicant: SOLAR JUNCTION CORPORATION, San Jose, CA (US)

(72) Inventors: TING LIU, SAN JOSE, CA (US); FERRAN SUAREZ, SAN JOSE, CA (US); ARSEN SUKIASYAN, SANTA CLARA, CA (US); JORDAN LANG, SUNNYVALE, CA (US)

(21) Appl. No.: 15/609,760

(22) Filed: May 31, 2017

Related U.S. Application Data
(60) Provisional application No. 62/350,430, filed on Jun. 15, 2016.

(51) Int. Cl. H01L 31/0735; H01L 31/0725; H01L 31/028; H01L 31/0216; H01L 31/0304; H01L 31/18; H01L 31/0687

(52) U.S. Cl. CPC H01L 31/0735; H01L 31/188; H01L 31/0725; H01L 31/0687; H01L 31/02167; H01L 31/03044; H01L 31/028; H01L 31/03048

(57) ABSTRACT

High efficiency dilute nitride bismide alloys and multijunction photovoltaic cells incorporating the high efficiency dilute nitride bismide alloys are disclosed. Bismuth-containing dilute nitride subcells exhibit a high efficiency across a broad range of irradiance energies, a high short circuit current density, and a high open circuit voltage.

This application claims the benefit under 35 U.S.C. §119(e) of U.S. Provisional Application No. 62/350,430 filed on Jun. 15, 2016, which is incorporated by reference in its entirety.

### FIELD

The present invention relates multijunction photovoltaic cells in which at least one or more subcells within the multijunction photovoltaic cell comprises a base layer formed of a bismuth-containing dilute nitride material. A bismuth-containing dilute nitride subcell exhibits a high efficiency across a broad range of irradiance energies, a high short circuit current density, and a high open circuit voltage.

### BACKGROUND

The present invention relates to multijunction photovoltaic cells, and in particular to high efficiency multijunction photovoltaic cells comprising at least one subcell formed from a bismuth-containing dilute nitride alloy. Dilute nitrides are a class of III-V alloy materials (alloys having one or more elements from Group III in the periodic table along with one or more elements from Group V in the periodic table) with small fractions (less than 15 atomic percent, for example) of nitrogen. Practitioners skilled in the art can identify III-V elements by standard chemical symbols, names and abbreviations. Multijunction photovoltaic cells made primarily of III-V semiconductor alloys are known to produce photovoltaic cell efficiencies exceeding efficiencies of other types of photovoltaic materials. As part of a terrestrial concentrating photovoltaic system, these III-V photovoltaic cells perform with efficiencies that can exceed 40% under concentrations equivalent to several hundred suns. The high efficiencies of dilute nitride-containing photovoltaic cells also make these photovoltaic cells good candidates for use in space.

Dilute nitride bismide subcells provided by the present disclosure can be incorporated into multijunction photovoltaic cells such as 3-junction, 4-junction, 5-junction, and 6-junction multijunction photovoltaic cells. When the dilute nitride subcell is the current limiting subcell of a multijunction cell, the efficiency of the multijunction photovoltaic cell will improve by about the same amount as the improvement in the efficiency of the dilute nitride subcell. For example, a 1% improvement in the efficiency of a current-limiting dilute nitride subcell will result in an improvement in the multijunction photovoltaic cell efficiency of about 1%.

Seemingly small improvements in the efficiency of a dilute nitride subcell can result in significant improvements in the efficiency of a multijunction photovoltaic cell. Again, seemingly small improvements in the overall efficiency of a multijunction photovoltaic cell can result in dramatic improvements in output power, reduce the area of a photovoltaic array, and reduce costs associated with installation, system integration, and deployment.

Photovoltaic cell efficiency is important as it directly affects the photovoltaic module power output. For example, assuming a 1 m² photovoltaic panel having an overall 24% conversion efficiency, if the efficiency of multi junction photovoltaic cells used in a module is increased by 1% such as from 40% to 41% under 500 suns, the module output power will increase by about 2.7 KW.

Normally a photovoltaic cell contributes around 20% to the total cost of a photovoltaic power module. Higher photovoltaic cell efficiency means more cost effective modules. Fewer photovoltaic devices are then needed to generate the same amount of output power, and higher power with fewer devices leads to reduced system costs, such as costs for mounting racks, hardware, wiring for electrical connections, etc. In addition, by using high efficiency photovoltaic cells, to generate the same power, less land area, fewer support structures, and lower labor costs are required for installation.

Photovoltaic modules are a significant component in spacecraft power systems. Lighter weight and smaller photovoltaic modules are always preferred because the lifting cost to launch satellites into orbit is super expensive. Photovoltaic cell efficiency is especially important for space power applications to reduce the mass and fuel penalty due to large photovoltaic arrays. The higher specific power (watts generated over photovoltaic array mass), which indicates how much power one array will generate for a given launch mass, can be achieved with more efficient photovoltaic cells since the size and weight of the photovoltaic array would be less for getting the same power output.

As an example, compared to a nominal photovoltaic cell having a 30% conversion efficiency, a 1.5% increase in multijunction photovoltaic cell efficiency can result in a 4.5% increase in output power, and a 3.5% increase in multijunction photovoltaic cell efficiency can result in a 11.5% increase in output power. For a satellite having a 60 kW power requirement, the use of higher efficiency subcells can result in photovoltaic cell module cost savings from $0.5 million to $1.5 million, and a reduction in photovoltaic array surface area of 15.6 m² to 6.4 m², for multijunction photovoltaic cells having increased efficiencies of 1.5% and 3.5%, respectively. The overall cost savings will be even greater when costs associated with system integration and launch are taken into consideration.

Multiple subcells, or junctions, are connected through tunnel junctions to form a multijunction photovoltaic cell, where the subcell base layers are either lattice-matched to the underlying substrate or are grown over metamorphic layers. The increase in efficiency is largely due to less light energy being lost as heat, as the additional subcells allow more of the incident photons to be absorbed by semiconductor materials with band gaps closer to the energy level of the incident photons. Series resistance losses are lower in these multijunction photovoltaic cells compared to other photovoltaic cells due to lower operating currents. At higher concentrations of sunlight, the reduced series resistance losses become more pronounced. Depending on the band gap of the bottom subcell, the collection of a wider range of photons in the solar spectrum may also contribute to the increased efficiency. Each subcell comprises a functional p-n junction and other layers, such as front surface field (FSF) and back surface field (BSF) layers.

Dilute nitride semiconductor materials are advantageous as multijunction photovoltaic cell materials because the lattice constant can be varied substantially to match a broad range of substrates and/or subcells formed from materials other than dilute nitrides. U.S. Pat. No. 9,252,315 discloses Ga₁₋ₓInₓN_{y}As_{1-y-z}Sb_{z} semiconductor materials with a composition range of 0.07≦x≦0.18, 0.025≦y≦0.04 and 0.001≦z≦0.03, with a band gap of 0.9 eV to 1.1 eV, and that are substantially lattice matched to gallium arsenide or germanium substrates. The lattice constant and band gap can be controlled by the relative fractions of the different group IIIA and group VA elements. Thus, by tailoring the compositions (i.e., the elements and atomic percentages) of a dilute nitride material, a wide range of lattice constants and band gaps may be obtained. Further, high quality material may be obtained by optimizing the composition around a specific lattice constant and band gap, while limiting the total antimony content to no more than 20 percent of the Group V lattice sites. U.S. Pat. Nos. 7,807,921 and 9,035,367 disclose metamorphic multijunction solar cells that require relatively thick buffer layers to accommodate differences in the lattice constants of the various materials. This is produced by changing the composition of the buffer layers during epitaxy to gradually change the lattice parameter this is a complex operation that introduces additional defects into the device structure. In addition, these additional epitaxial layers lead to thicker, heavier devices that not only cause an increase in the direct cost of each solar cell with integrated coverglass (CIC), but also increase deployment costs associated with launch mass. For at least these reasons, lattice-matched designs have significant advantages compared to metamorphic structures.

Antimony is believed to act as a surfactant to promote smooth growth morphology of the III-AsNV alloys. Antimony can facilitate uniform incorporation of nitrogen, minimize the formation of nitrogen-related defects, and reduce the alloy band gap which makes lower band gaps accessible. However, there are additional defects created by antimony and therefore it is desirable that the total concentration of antimony be limited to no more than 20 percent, and in certain embodiments, to no more than 10 percent, of the Group V lattice sites. Further, the upper limit on antimony content decreases with decreasing nitrogen content. Alloys that include indium can have even lower limits to the antimony content because indium can reduce the amount of antimony needed to tailor the lattice constant. For alloys that include indium, the total antimony content may be limited to no more than 5 percent of the Group V lattice sites.

U.S. Pat. No. 8,962,993 discloses multijunction photovoltaic cells with at least one Ga₁₋ₓInₓN_{y}As_{1-y-z}Sb_{z} subcell with a composition range of 0.08≦x≦0.24, 0.02≦y≦0.05 and 0.001≦z≦0.014, and substantial lattice-matching to silicon, germanium, silicon germanium, gallium arsenide and indium phosphide. U.S. Application Publication No. 2017/0110613 discloses high quality photovoltaic cells with at least one Ga₁₋ₓInₓN_{y}As_{1-y-z}Sb_{z} subcell with a composition range of 0.03≦x≦0.19, 0.008≦y≦0.055, and 0.001≦z≦0.05, and a band gap 0.8 eV to 1.3 eV. In these publications, antimony was the only Group V element used in the dilute nitride compositions; incorporation of bismuth into dilute nitrides was not disclosed.

Although the use of bismuth as a surfactant for GaInNAs and GaAsN growth has been investigated, the use of bismuth in fabricating a reliable high-efficiency dilute nitride photovoltaic cell has not been demonstrated. Bismuth is useful in extending the range of compositions and growth conditions that can be used to produce high-quality epitaxial semiconductor layers (Young et al., J. Crystal Growth 279 (2005) 316-320; Liu et al., J. Crystal Growth 304 (2007) 402-406; Ptak et al., J. Vac. Sci. Technol. B. 26, 1053 (2008)). In addition to reducing surface aggregation of indium and nitrogen, bismuth does not increase dark current as is the case with antimony. In contrast, bismuth appears to increase net donor concentration in devices which can cause a p-type base layer to convert to an n-type layer. Unfortunately, determining the precise amount of bismuth incorporation is problematic—small differences in atomic percentages can lead to large morphological effects, requiring extensive exploration, not only with the amount of bismuth used, but also with the processing parameters required to produce a high-efficiency dilute nitride multijunction photovoltaic cell. In PCT International Application Publication No. WO 2014/202983, Sweeney et al. discuss a single junction photovoltaic cell that incorporates bismuth into GaAs, GaAsN and GaInAsBi, but do not disclose functional results demonstrating the efficiency of the photovoltaic cells. Furthermore, in the U.S. Application Publication No. 2014/0326301, Johnson discloses a two junction (2J) (In)GaAsNBi/SiGe(Sn) structure that can be incorporated into four-junction (4J) and five junction (5J) solar cells. However, Johnson does not include performance characteristics of these 2J, 4J, or 5J structures, which brings into question the functionality of the solar cells disclosed. Research and development efforts with dilute nitrides are fraught with unpredictability as expertise in conventional semiconductor materials does not enable one to successfully design a high efficiency photovoltaic cell with dilute nitrides without significant experimentation.

GaInNAsBi subcells exhibiting high efficiency and multijunction photovoltaic cells incorporating GaInNAsBi subcells that exhibit high efficiency are desired. The present disclosure reports performance values for specific dilute nitride bismide compositions, demonstrating solar cells that operate at high efficiency.

### SUMMARY

Dilute nitride compositions that have low bismuth content and enhanced nitrogen content are disclosed. Examples of these dilute nitrides include Ga₁₋ₓInₓN_{y}As_{1-y-z}Bi_{z}, Ga₁₋ₓInₓN_{y}As_{1-y-z1-z2}Sb_{z1}Bi_{z2}, GaN_{y}As_{1-y-z}Bi_{z} and GaN_{y}As_{1-y-z1-z2}Sb_{z1}Bi_{z2}. The disclosed dilute nitride bismide compositions allow the fabrication of subcells with band gaps that are design-tunable in the range of 0.8 eV to 1.3 eV, that are substantially lattice matched to GaAs or Ge substrates, exhibit high short circuit currents, and exhibit high open circuit voltages. Bismide alloys can be grown by molecular beam epitaxy (MBE) or by metalorganic chemical vapor deposition (MOCVD).

According to the present invention, multijunction photovoltaic cells comprise a dilute nitride bismide subcell, wherein the dilute nitride bismide subcell is characterized by, an efficiency of at least 70% at an irradiance energy from 1.38 eV to 1.30 eV, and an efficiency of at least 80% at an irradiance energy from 1.38 eV to 1.30 eV; an efficiency of at least 70% at an irradiance energy from 1.38 eV to 1.18 eV, and an efficiency of at least 80% at an irradiance energy from 1.38 eV to 1.30 eV; an efficiency of at least 70% at an irradiance energy from 1.38 eV to 1.10 eV, and an efficiency of at least 80% at an irradiance energy from 1.38 eV to 1.18 eV; an efficiency of at least 70% at an irradiance energy from 1.38 eV to 1.03 eV, and an efficiency of at least 80% at an irradiance energy from 1.38 eV to 1.15 eV; an efficiency of at least 70% at an irradiance energy from 1.38 eV to 0.99 eV, and an efficiency of at least 80% at an irradiance energy from 1.38 eV to 1.15 eV; or an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.15 eV; wherein the efficiency is measured at a junction temperature of 25° C.

According to the present invention, multijunction photovoltaic cells comprise a dilute nitride bismide subcell comprising Ga₁₋ₓInₓN_{y}As_{1-y-z}Bi_{z}, wherein the content values for x, y, and z are within composition ranges as follows: 0.03≦x≦0.19, 0.008≦y≦0.055, and 0.001≦z≦0.09.

According to the present invention, multijunction photovoltaic cells comprise a dilute nitride bismide subcell comprising Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09.

According to the present invention, multijunction photovoltaic cells comprise a dilute nitride bismide subcell comprising GaN_{y}As_{1-y-z}Bi_{z}, wherein the content values for y and z are within composition ranges as follows: 0.001≦y≦0.055, and 0.001≦z≦0.09.

According to the present invention, multijunction photovoltaic cells comprise a dilute nitride bismide subcell comprising GaN_{y}As_{1-y-z1-z2}Sb_{z1}Bi_{z2}, wherein the content values for y and z are within composition ranges as follows: 0.001≦y≦0.055, and 0.001≦z1+z2≦0.09.

According to the present invention, multijunction photovoltaic cells comprise a dilute nitride bismide subcell characterized by a Eg/q-Voc equal to or greater than 0.55 V measured using a 1 sun AM1.5D spectrum at a junction temperature of 25° C.

According to the present invention, multijunction photovoltaic cells comprise a dilute nitride bismide subcell characterized by a Eg/q-Voc from 0.4 V to 0.7 V measured using a 1 sun AM1.5D spectrum at a junction temperature of 25° C.

According to the present invention, a dilute nitride bismide subcell is characterized by a bandgap within a range from 0.85 eV to 1.25 eV.

According to the present invention, a dilute nitride bismide subcell is substantially lattice-matched to a GaAs substrate or to a Ge substrate.

According to the present invention, a dilute nitride bismide subcell is p-doped or n-doped.

According to the present invention, a dilute nitride bismide subcell is characterized by a base thickness of 0.4 micron to 3.5 micron.

According to the present invention, a multijunction photovoltaic cell comprises at least three subcells.

According to the present invention, a photovoltaic module comprises at least one multijunction photovoltaic cell of the present disclosure.

According to the present invention, a photovoltaic system comprises at least one multijunction photovoltaic cell of the present disclosure.

According to the present invention, a dilute nitride bismide alloy comprises Ga₁₋ₓInₓN_{y-z}Bi_{z}, wherein the content values for x, y, and z are within composition ranges as follows: 0.03≦x≦0.19, 0.008≦y≦0.055, and 0.001≦z≦0.09.

According to the present invention, a dilute nitride bismide alloy comprises Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09.

According to the present invention, a dilute nitride bismide alloy comprises GaN_{y}As_{1-y-z}Bi_{z}, wherein the content values for y and z are within composition ranges as follows: 0.001≦y≦0.055, and 0.001≦z≦0.09.

According to the present invention, a dilute nitride bismide alloy comprises GaN_{y}As_{1-y-z1-z2}Sb_{z1}Bi_{z2}, wherein the content values for y and z are within composition ranges as follows: 0.001≦y≦0.055, and 0.001≦z1+z2≦0.09.

According to the present invention, a semiconductor device comprises a dilute nitride bismide alloy provided by the present disclosure.

According to the present invention, a photovoltaic cell, a multijunction photovoltaic cell, a laser, a photodiode, or a transistor comprises a dilute nitride bismide alloy provided by the present disclosure.

### BRIEF DESCRIPTION OF THE DRAWINGS

Those skilled in the art will understand that the drawings described herein are for illustration purposes only. The drawings are not intended to limit the scope of the present disclosure.

FIG. 1 shows the measured efficiency as a function of irradiance wavelength for GaInNAsSb subcells having a band gap within the range from 0.82 eV to 1.24 eV.

FIG. 2 shows the measured open circuit voltage (Voc) for GaInNAsSb subcells having a band gap within the range from 0.82 eV to 1.24 eV.

FIG. 3A shows a schematic cross-section of a dilute nitride subcell, wherein the dilute nitride base is selected from the following: GaInNAsSb, GaInNAsBi, GaInNAsSbBi, GaAsNSb, GaAsNBi and GaAsNSbBi.

FIG. 3B shows a detailed schematic cross-section illustrating an example of a dilute nitride subcell with an n-on-p heterojunction.

FIG. 3C shows a detailed schematic cross-section illustrating an example of a dilute nitride subcell with an n-on-p homojunction.

FIG. 4 shows a schematic cross-section of a three junction (3J) photovoltaic cell incorporating invention dilute nitride bismide subcell.

FIG. 5 shows examples of subcell compositions for three-junction (3J), four junction (4J), five junction (5J) and six-junction (6J) photovoltaic cells.

FIG. 6 shows an example of the composition and function of certain layers of a four-junction (4J) (AlIn)GaP/(AlIn)GaAs/GaInNAsBi(Sb)/Ge multijunction photovoltaic cell.

### DETAILED DESCRIPTION

Multijunction photovoltaic cells comprising at least one dilute nitride antimonide alloy have been fabricated. The dilute nitrides include, for example, GaInNAsSb and GaNAsSb. These dilute nitrides can form the base layer of one or more subcells, which can be incorporated into a multijunction photovoltaic cell that performs at high efficiencies. Dilute nitrides comprise low antimony and/or bismuth and enhanced nitrogen concentrations. Each subcell or junction within a multijunction photovoltaic cell is designed to have a specific band gap, enabling the subcell to capture incident photons within a specific energy range. Collectively, the subcells forming a multijunction solar cell can absorb incident photons having a wide range of energies which leads to a higher efficiency photovoltaic cell. The band gaps and compositions of the dilute nitride subcells can be tailored so that the short-circuit current produced by the dilute nitride subcells will be the same as or slightly greater than the short-circuit current of the other subcells in the photovoltaic cell.

Dilute nitride bismide compositions include GaInNAsBi, GaInNAsSbBi, GaNAsBi, and GaNAsSbBi. Dilute nitrides such as GaInNAs are useful materials in multijunction solar cells for their ability to provide band gaps less than 1.2 eV and to lattice match to substrates such as GaAs and Ge. To improve the properties of these alloys, a surfactant such as Sb or Bi can be used to improve the material quality. Antimony-containing dilute nitrides such a GaInNAsSb have been developed that exhibit high efficiencies over a wide range of photon energies. Bismuth alloys have been less well studied and in particular in the development of high efficiency dilute nitride photovoltaic cells. Based on the similar electronic properties, and the demonstrated ability of bismuth to be incorporated into dilute nitrides such as GaInNAs, it is expected that high efficiency dilute nitride bismide alloys will have compositions and corresponding properties similar to those of antimony alloys.

The present disclosure describes bismuth-containing dilute nitrides (also referred to as dilute nitride bismides) that are lattice-matched in a multijunction solar cell on n-type substrates. The above-mentioned publications U.S. Pat. No. 9,252,315, U.S. Pat. No. 8,962,993 and U.S. Application Publication No. 2017/0110613 disclose GaInNAsSb devices grown on p-type substrates antimony was the preferred surfactant for incorporation into dilute nitrides, creating an intrinsically doped n-type dilute nitride antimonide junction overlying a p-type substrate. For devices requiring the use of an n-type substrate, bismuth would be the preferred surfactant to produce an intrinsically doped p-type dilute nitride junction. PCT International Publication No. WO 2014/202983 describes standalone dilute nitride bismides comprising three and four elements on n-type substrates. The present disclosure describes elemental compositions for dilute nitride bismides that comprise five and six elements. Lattice-matching and band gap tunability become increasingly complex in quinary and senary alloys. The embodiments in the present disclose demonstrate success in overcoming these complexities.

Ga₁₋ₓInₓN_{y}As_{1-y-z}Bi_{z} subcells are described. The ability to provide high efficiency multijunction photovoltaic cells incorporating a Ga₁₋ₓInₓN_{y}As_{1-y-z}Bi_{z} subcell is based on the ability to provide a high quality Ga₁₋ₓInₓN_{y}As_{1-y-z}Bi_{z} subcell that can be lattice-matched to a variety of semiconductors including germanium and gallium arsenide, and that can be tailored to have a band gap within the range of 0.8 eV to 1.3 eV. Factors that contribute to providing high efficiency Ga₁₋ₓInₓN_{y}As_{1-y-z}Bi_{z} subcells include, for example, the band gaps of the individual subcells, which in turn can depend on the semiconductor composition of the subcells, doping levels and doping profiles, thicknesses of the subcells, quality of lattice matching, defect densities, growth conditions, annealing temperatures and temperature profiles, and impurity levels.

Various metrics can be used to characterize the quality of a Ga₁₋ₓInₓN_{y}As_{1-y-z}Bi_{z} subcell including, for example, the Eg/q-Voc, the efficiency over a range of irradiance energies, the open circuit voltage Voc, and the short circuit current density Jsc.

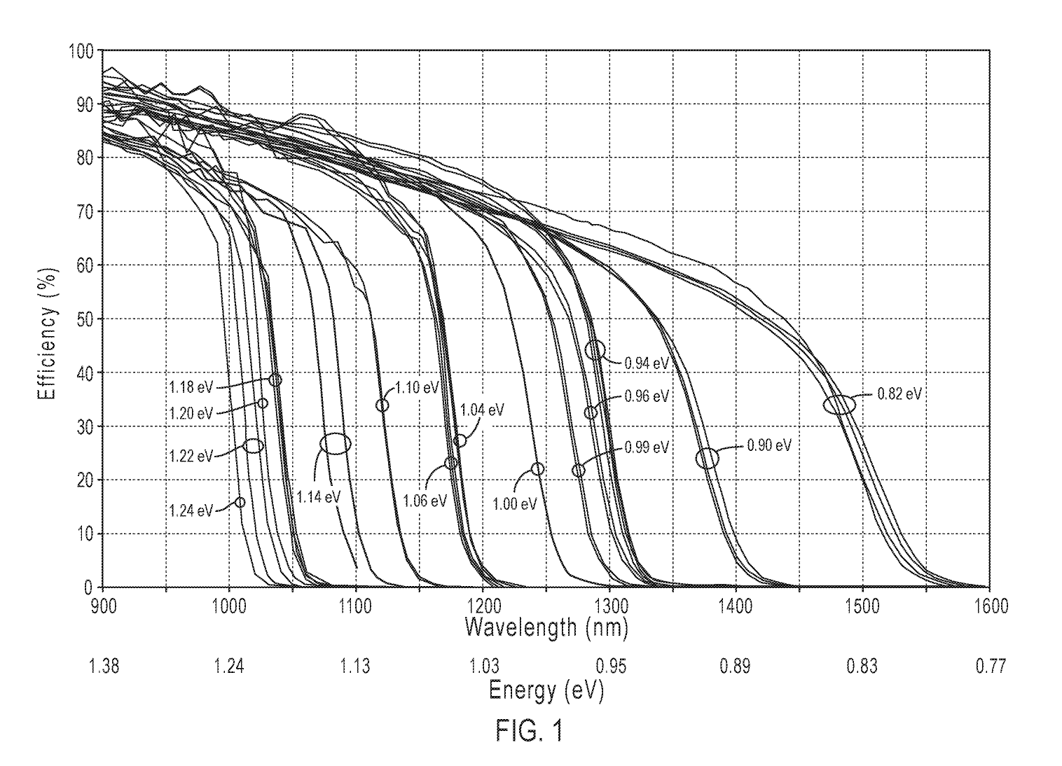

The quality of a Ga₁₋ₓInₓN_{y}As_{1-y-z}Bi_{z} subcell can be characterized by a curve of the efficiency as a function of irradiance wavelength or irradiance energy. In general, a high quality Ga₁₋ₓInₓN_{y}As_{1-y-z}Bi_{z} subcell will exhibit an efficiency of at least 60%, at least 70% or at least 80% over a wide range of irradiance wavelengths/energies. FIG. 1 shows the dependence of the efficiency as a function of irradiance wavelength for Ga₁₋ₓInₓN_{y}As_{1-y-z}Sb_{z} subcells having band gaps within the range from about 0.8 eV to about 1.3 eV.

The irradiance wavelengths for which the efficiencies of a Ga₁₋ₓInₓN_{y}As_{1-y-z}Sb_{z} subcell referred to in FIG. 1 can be greater than 70% and greater than 80% is summarized in Table 1.

TABLE 1
Dependence of efficiency of Ga₁₋ₓInₓN_{y}As_{1-y-z}Sb_{z} subcells.

| GaInNAsSb Band Gap | | | | | |
|---|---|---|---|---|---|
| Wavelength | Energy | Efficiency (nm/eV) | | | |
| (nm) | (eV) | >70% | | >80% | |
| 1025 | 1.21 | <800/<1.55 | 1015/1.22 | 830/1.50 | 985/1.26 |
| 1120 | 1.11 | <800/<1.55 | 1090/1.14 | 825/1.50 | 1035/1.20 |
| 1175 | 1.06 | <800/<1.55 | 1150/1.08 | 825/1.50 | 1105/1.12 |
| 1250 | 0.99 | <800/<1.55 | 1180/1.05 | 805/1.54 | 1120/1.11 |
| 1280 | 0.97 | <800/<1.55 | 1235/1.00 | 825/1.50 | 1150/1.08 |
| 1350 | 0.92 | <800/<1.55 | 1245/0.99 | 825/1.50 | 1120/1.11 |
| 1475 | 0.83 | <800/<1.55 | 1290/0.96 | 810/1.53 | 1105/1.12 |

Ga₁₋ₓInₓN_{y}As_{1-y-z}Bi_{z} subcells are expected to exhibit similar properties. A Ga₁₋ₓInₓN_{y}As_{1-y-z}Bi_{z} subcell can exhibit a high efficiency greater than 60%, greater than 70%, or greater than 80% over a broad irradiance wavelength range.

As shown in FIG. 1, the range of irradiance wavelengths over which a particular Ga₁₋ₓInₓN_{y}As_{1-y-z}Sb_{z} subcell exhibits a high efficiency ca be bounded by the band gap of a particular Ga₁₋ₓInₓN_{y}As_{1-y-z}Sb_{z} subcell. Measurements are not extended to wavelengths below 800 nm because in a practical photovoltaic cell, a germanium subcell can be used to capture and convert radiation at the shorter wavelengths. The efficiencies shown in FIG. 1 were measured at an irradiance of 1 sun (1,000 W/m²) with the AM1.5D spectrum at a junction temperature of 25° C., for a GaInNAsSb subcell thickness of 2 μm. One skilled in the art will understand how to extrapolate the measured efficiencies to other irradiance wavelengths/energies, subcell thicknesses, and temperatures.

A Ga₁₋ₓInₓN_{y}As_{1-y-z}Bi_{z} subcell can exhibit an efficiency of at least 80% at an irradiance energy from 1.4 eV to 1.24 eV; an efficiency of at least 80% at an irradiance energy from 1.24 eV to 1.03 eV; an efficiency of at least 70% at an irradiance energy from 1.03 eV to 0.95 eV; an efficiency of at least 60% at an irradiance energy from 0.95 eV to 0.89 eV; and/or an efficiency of at least 60% at an irradiance energy from 0.89 eV to 0.83 eV.

A Ga₁₋ₓInₓN_{y}As_{1-y-z}Bi_{z} subcell can exhibit an Eg/q-Voc of at least 0.55 V, at least 0.6 V, or at least 0.65 V over each respective range of irradiance energies. A Ga₁₋ₓInₓN_{y}As_{1-y-z}Bi_{z} subcell can exhibit an Eg/q-Voc within the range of 0.55 V to 0.70 V over each respective range of irradiance energies.

In addition to exhibiting a high efficiency over a broad range of irradiance wavelengths, the quality of a Ga₁₋ₓInₓN_{y}As_{1-y-z}Bi_{z} subcell can be reflected in a high short circuit current density Jsc, a low open circuit voltage Voc, and a high fill factor. Estimates for these parameters are provided for certain Ga₁₋ₓInₓN_{y}As_{1-y-z}Bi_{z} subcells having a band gap within the range from 0.9 eV to 1.0 eV in Table 2.

TABLE 2
Estimated properties of Ga₁₋ₓInₓN_{y}As_{1-y-z}Bi_{z} subcells.

| Band gap | Jsc range (mA/cm²) | | Voc range (V) | | Ga₁₋ₓInₓN_{y}As_{1-y-z}Bi_{z} Mole Fraction | | |
|---|---|---|---|---|---|---|---|
| (eV) | minimum | maximum | minimum | maximum | In(x) | N(y) | Bi(z) |
| 0.9 | 15 | 16.1 | 0.28 | 0.36 | 0.15-0.19 | 0.035-0.055 | 0.001-0.015 |
| 0.92 | 14.8 | 16.1 | 0.31 | 0.4 | 0.14-0.18 | 0.03-0.05 | 0.001-0.015 |
| 0.94 | 14.8 | 16 | 0.33 | 0.44 | 0.12-0.17 | 0.025-0.045 | 0.001-0.015 |
| 0.96 | 14.5 | 15.6 | 0.35 | 0.46 | 0.11-0.16 | 0.02-0.04 | 0.001-0.015 |
| 0.98 | 13.5 | 15 | 0.36 | 0.48 | 0.09-0.15 | 0.015-0.035 | 0.001-0.015 |
| 1 | 10.7 | 14.8 | 0.4 | 0.5 | 0.07-0.13 | 0.01-0.03 | 0.001-0.015 |

For each of the Ga₁₋ₓInₓN_{y}As_{1-y-z}Bi_{z} subcells presented in Table 2, the efficiency can be, for example, from 80% to 90%. The values can be measured using 1 sun AM1.5D illumination at a junction temperature of 25° C.

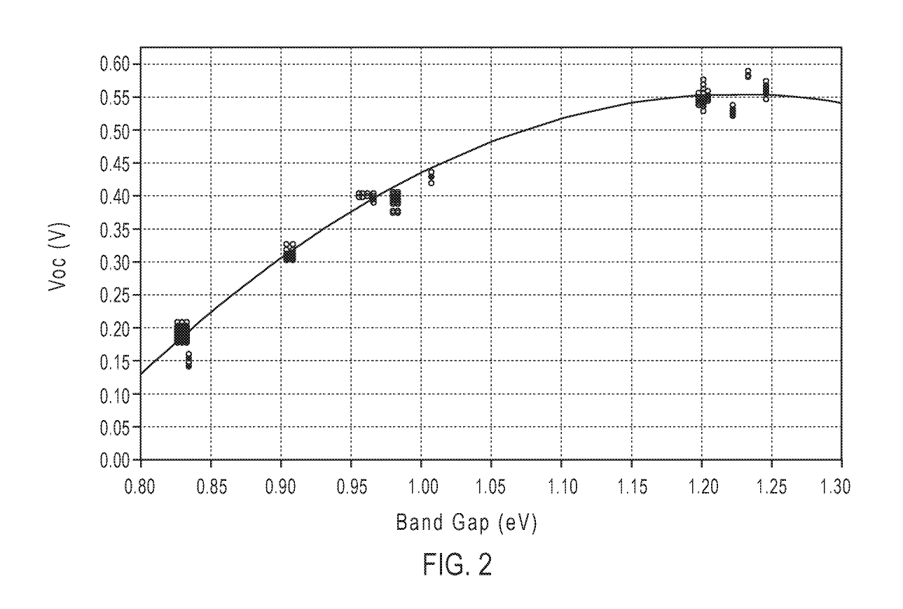

The quality of a Ga₁₋ₓInₓN_{y}As_{1-y-z}Bi_{z} composition provided by the present disclosure can also be reflected in the low open circuit voltage Voc, which can depend in part on the band gap of the Ga₁₋ₓ InₓN_{y}As_{1-y-z}Bi_{z} composition. The dependence of the open circuit voltage Voc with the band gap of a Ga₁₋ₓInₓN_{y}As_{1-y-z}Bi_{z} composition is shown in FIG. 2 the open circuit voltage Voc can change from about 0.2 V for a Ga₁₋ₓInₓN_{y}As_{1-y-z}Bi_{z} composition with a band gap of 0.85 eV, to an open circuit voltage Voc of about 0.55 V for a Ga₁₋ₓInₓN_{y}As_{1-y-z}Bi_{z} composition with a band gap of 1.25 eV. Ga₁₋ₓInₓN_{y}As_{1-y-z}Bi_{z} subcells exhibiting a band gap within the range from 0.8 eV to 1.3 eV can have values for x, y, and z of 0.03≦x≦0.19, 0.008≦y≦0.055, and 0.001≦z≦0.09.

In certain embodiments of dilute nitride bismides provided in the present disclosure, two group V elements are used in the composition, namely bismuth and antimony. In certain embodiments, the indium content is enhanced in the dilute nitride composition, while in others, indium is absent. In some embodiments, GaInNAsSbBi is composed of Ga₁₋ₓInₓN_{y}As_{1-y-z1-z2}Sb_{z1}Bi_{z2}, where the content values for x, y, and z are within composition ranges as follows: 0.03≦x≦0.19, 0.008≦y≦0.055, and 0.001≦z1+z2≦0.09. In some embodiments, GaNAsBi is composed of GaN_{y}As_{1-y-z}Bi_{z}, where the content values for y and z are within composition ranges as follows: 0.001≦y≦0.055, and 0.001≦z≦0.09. In some embodiments, GaNAsSbBi is composed of GaN_{y}As_{1-y-z1-z2}Sb_{z1}Bi_{z2}, where the content values for y and z are within composition ranges as follows: 0.001≦y≦0.055, and 0.001≦z1+z2≦0.09.

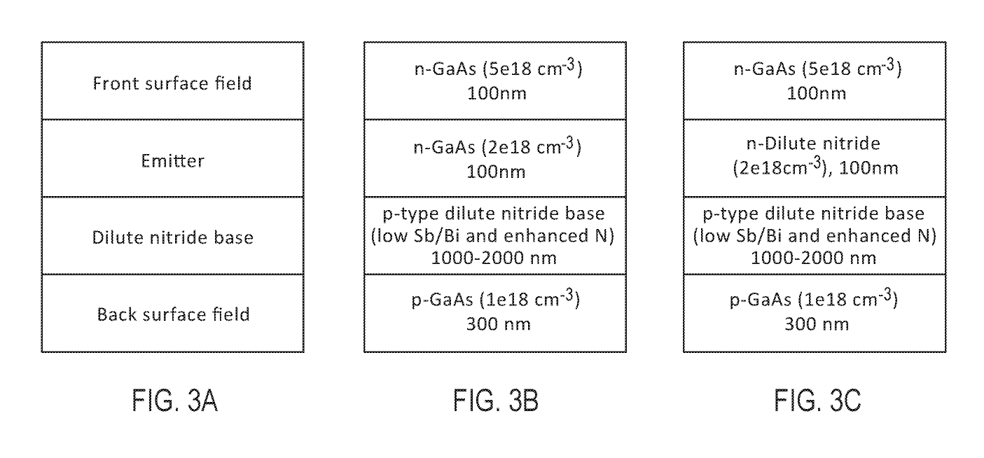

The various dilute nitrides described in this disclosure can be used to form the dilute nitride base layer of a subcell. FIG. 3A shows a schematic cross-section of a generic dilute nitride subcell. In operation, a front surface field (FSF) is the topmost layer of a subcell and faces incident radiation. A FSF overlies an emitter layer which overlies a dilute nitride base layer. An emitter layer can comprise a III-V material (such as GaAs as shown in FIG. 3B). A dilute nitride base layer can comprise GaInNAsSb, GaInNAsBi, GaInNAsSbBi, GaAsNSb, GaAsNBi, GaAsNSbBi, or other alloy that comprises low bismuth and enhanced nitrogen concentrations, or low bismuth, low antimony, and enhanced nitrogen concentrations. A dilute nitride layer base overlies a back surface field (BSF) (such as GaAs as shown in FIG. 3B) which is the bottom-most layer within the subcell. Various dopants may be present in the FSF, emitter, dilute nitride base and/or BSF layers at concentrations selected for n- or p-doping throughout all or within a portion of each layer.

In certain embodiments, the thickness of a FSF can be from about 10 nm to about 500 nm, from about 10 nm to about 300 nm, from about 10 nm to about 150 nm, and in certain embodiments, from about 10 nm to about 50 nm. In certain embodiments, the thickness of the FSF can be from about 50 nm to about 350 nm, from about 100 nm to about 300 nm, and in certain embodiments, from about 50 nm to about 150 nm.

In certain embodiments, the thickness of an emitter layer can be from about 10 nm to about 300 nm, from about 20 nm to about 200 nm, from about 50 nm to about 200 nm, and in certain embodiments, from about 75 nm to about 125 nm.

In certain embodiments, the thickness of a dilute nitride base layer can be from about 0.1 μm to about 6 μm, from about 0.1 μm to about 4 μm, from about 0.1 μm to about 3 μm, from about 0.1 μm to about 2 μm, and in certain embodiments, from about 0.1 μm to about 1 μm. In certain embodiments, the thickness of a base layer can be from about 0.5 μm to about 5 μm, from about 1 μm to about 4 μm, from about 1.5 μm to about 3.5 μm, and in certain embodiments, from about 2 μm to about 3 μm.

In certain embodiments, the thickness of a BSF layer can be from about 10 nm to about 500 nm, from about 50 nm to about 300 nm, and in certain embodiments, from about 50 nm to about 150 nm.

FIG. 3B illustrates an embodiment of a dilute nitride subcell with an n-on-p heterojunction. The base layer can be 1000 nm to 2000 nm thick and can comprise an n-type dilute nitride comprising low bismuth and enhanced nitrogen concentrations, or low bismuth, low antimony, and enhanced nitrogen concentrations. The BSF can comprise a 300 nm-thick layer of p-GaAs where dopants may be present up to 1e18 atoms per cm³. The FSF can comprise a 100 nm-thick layer of n-GaAs where dopants may be present up to 5e18 atoms per cm³, which overlies a 100 nm-thick emitter layer of n-GaAs where dopants may be present up to 2e18 atoms per cm³.

FIG. 3C illustrates an embodiment of a dilute nitride subcell with an n-on-p homojunction. The n-doped emitter and p-doped base layers can comprise low bismuth and enhanced nitrogen concentrations, or low bismuth, low antimony, and enhanced nitrogen concentrations. The dilute nitride emitter can be 100-nm thick and the base layer can be from 1,000 nm to 2,000 nm thick. The BSF can comprise a 300 nm-thick layer of p-GaAs where dopants may be present up to 1e18 atoms per cm³. The FSF can comprise a 100 nm-thick layer of n-GaAs where dopants may be present up to 5e18 atoms per cm³, which can overly a 100 nm-thick emitter layer of n-GaAs where dopants may be present up to 2e18 atoms per cm³. In other embodiments, an n-i-p junction can be present to modify the subcell current, whereby an intrinsic region is included in the subcell.

In some embodiments, a dilute nitride subcell can be configured to have a p-on-n junction polarity. The p-on-n junction can comprise a heterojunction or homojunction design. In some embodiments, a p-i-n junction can be present to modify subcell current, whereby an intrinsic region is included in the subcell.

Dilute nitride subcells can be incorporated into a multijunction photovoltaic cell. The various subcells can be connected in series via tunnel junctions that are designed to have minimal light absorption. Light absorbed by tunnel junctions is not converted into electricity by a photovoltaic cell, and thus if the tunnel junctions absorb significant amounts of light, it will not be possible for the efficiencies of the multijunction photovoltaic cells to exceed those of the best triple junction (3J) photovoltaic cells in today's market. Accordingly, it is desirable that the tunnel junctions be very thin, for example, less than 40 nm, and/or be made of materials with band gaps equal to or greater than the subcells immediately above the respective tunnel junction. An example of a tunnel junction fitting these criteria is a GaAs/AlGaAs tunnel junction, where each of the GaAs and AlGaAs layers forming the tunnel junction has a thickness between 5 nm and 30 nm. The GaAs layer can be doped with Te, Se, S and/or Si, and the AlGaAs layer can be doped with C.

In operation, a multijunction photovoltaic cell can be configured such that the subcell having the highest band gap faces the incident photovoltaic radiation, with subcells characterized by increasingly lower band gaps underlying or beneath the uppermost subcell. The band gaps of a subcell can be dictated, at least in part, by the band gap of the bottom subcell, the thicknesses of the subcell layers, and the incident spectrum of light. All subcells within a multijunction photovoltaic cell can be substantially lattice-matched to each of the other subcells. A multijunction photovoltaic cell may be fabricated on a substrate such as a germanium substrate. In certain embodiments, the substrate can comprise gallium arsenide, indium phosphide, germanium, or silicon. In certain embodiments, all of the subcells can be substantially lattice-matched to each of the other subcells and to the substrate. As used herein, “substantially lattice matched” means that the in-plane lattice constants of the materials in their fully relaxed states differ by less than 0.6% when the materials are present in thicknesses greater than 100 nm.

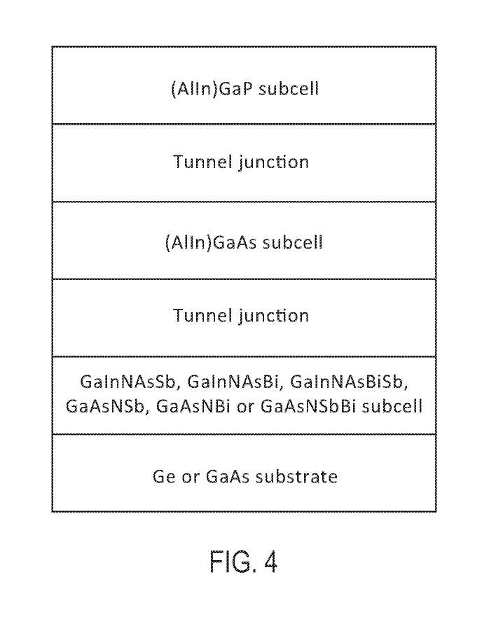

FIG. 4 illustrates an embodiment of the invention in which a 3J photovoltaic cell incorporates a dilute nitride subcell as its third subcell (J3). The substrate layer is the bottom-most layer of the photovoltaic cell and comprises germanium or gallium arsenide. A dilute nitride subcell forms the J3 of the photovoltaic cell, overlying the substrate layer. The dilute nitride subcell can comprise GaInNAsSb, GaInNAsBi, GaInNAsSbBi, GaAsNSb, GaAsNBi, GaAsNSbBi, and other alloys that comprise low antimony and/or bismuth and enhanced nitrogen concentrations. The second subcell (J2) is an (aluminum indium) gallium arsenide subcell and the first subcell (J1) is an (aluminum indium) gallium phosphide subcell. Practitioners in the art can recognize that elements in parenthesis may be absent or present within the alloy composition. J1, J2 and J3 are connected in series via tunnel junctions. The J1 is the top-most subcell of the photovoltaic device and faces incident light.

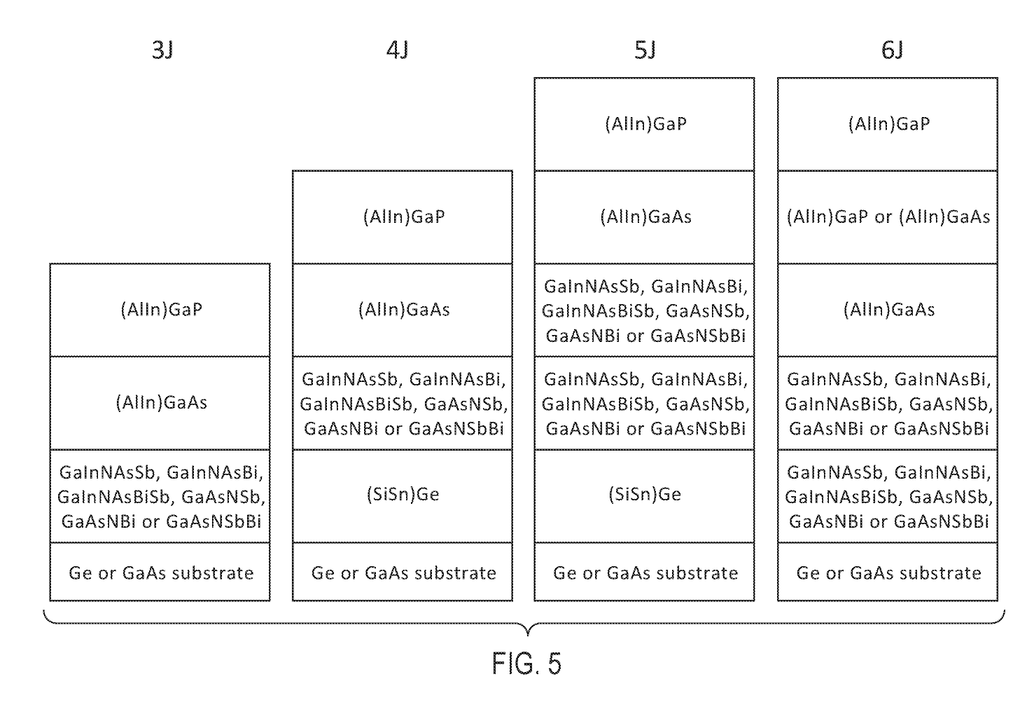

FIG. 5 illustrates three junction (3J), four junction (4J), five junction (5J) and six junction (6J) photovoltaic cell embodiments of the invention. Subcell base materials can be chosen based on desired band gaps, and semiconductor materials can be grown via epitaxy on a germanium or gallium arsenide substrate. In the 3J embodiment, the subcell materials from top to bottom are (Al,In)GaP/(Al,In)GaAs/dilute nitride. In the 4J embodiment of the invention, the subcell materials from top to bottom are (Al,In)GaP/(Al,In)GaAs/dilute nitride/(Si,Sn)Ge. The 5J embodiment comprises two dilute nitride subcells; the subcell materials from top to bottom are (Al,In)GaP/(AlIn)GaAs/dilute nitride/dilute nitride/(Si,Sn)Ge.

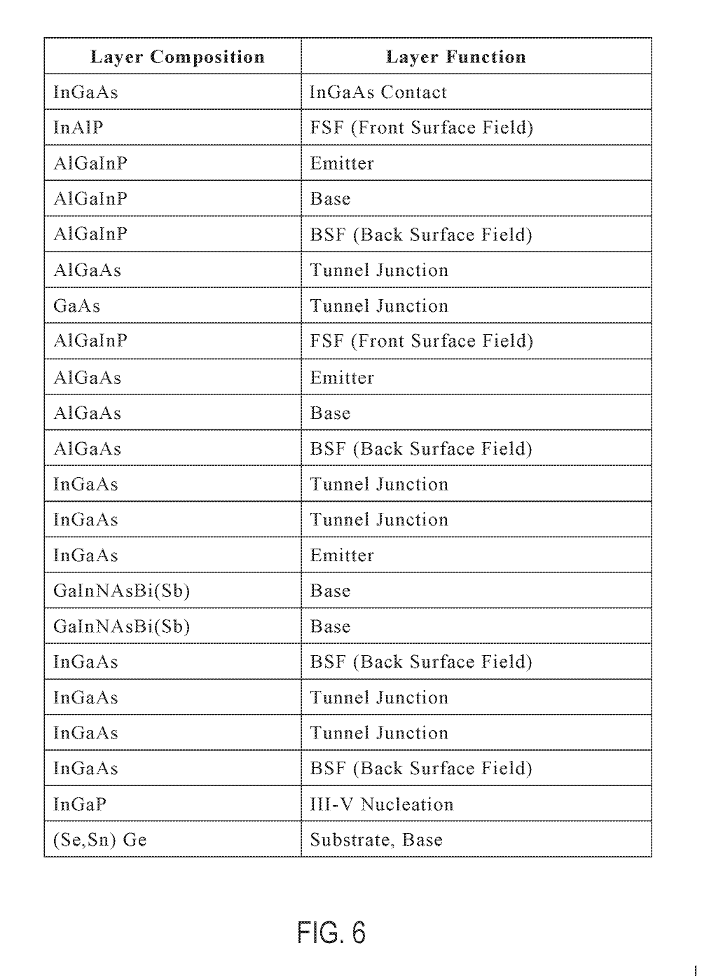

In each of the embodiments described and illustrated herein, additional semiconductor layers can be present to create a photovoltaic cell device. Specifically, cap or contact layer(s), anti-reflection coating (ARC) layers, and/or electrical contacts (also denoted as the metal grid) can be formed above the top subcell, and buffer layer(s), the substrate or handle, and bottom contacts can be formed or be present below the bottom subcell. In certain embodiments, the substrate may also function as the bottom subcell, such as in a germanium substrate. Other semiconductor layers, such as additional tunnel junctions, may also be present. Multijunction photovoltaic cells may also be formed without one or more of the layers listed above, as known to those skilled in the art. FIG. 6 shows an example structure of a 4J photovoltaic cell illustrating possible additional semiconductor layers that may be present in a multijunction photovoltaic cell. These additional layers can include electrical contacts, buffer layers, tunnel junctions, FSF, window, emitter, BSF, and/or nucleation layers.

The semiconductor layers can be grown by MBE or MOCVD methods known to those skilled in the art using suitable conditions such as, for example, pressure, concentration, temperature, and time to provide high quality multijunction photovoltaic cells. Each of the base layers can be lattice matched to each of the other base layers and to the germanium or gallium arsenide substrate.

In certain embodiments provided by the present disclosure, the semiconductor layers composing the photovoltaic cell, excepting the substrate, can be fabricated using molecular beam epitaxy (MBE) and/or chemical vapor deposition (CVD). In certain embodiments, more than one material deposition chamber can be used for the deposition of the semiconductor layers comprising the photovoltaic cell. The materials deposition chamber is the apparatus in which the semiconductor layers composing the photovoltaic cell are deposited. The pressure inside the chamber may range from 10⁻¹¹ Torr to 10³ Torr. In certain embodiments, the alloy constituents are deposited via physical and/or chemical processes. Each materials deposition chamber can have different configurations which allow for the deposition of different semiconductor layers and can be independently controlled from other materials deposition chambers. The semiconductor layers may be fabricated using metal organic chemical vapor deposition (MOCVD), MBE, or by other methods, including a combination of any of the foregoing.

The movement of the substrate and semiconductor layers from one materials deposition chamber to another is defined as a transfer. For example, a substrate can be placed in a first materials deposition chamber, and then the buffer layer(s) and the bottom subcell(s) are deposited. Then the substrate and semiconductor layers are transferred to a second materials deposition chamber where the remaining subcells are deposited. The transfer may occur in vacuum, at atmospheric pressure in air or another gaseous environment, or in any environment in between. The transfer may further be between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

In certain embodiments provided by the present disclosure, a plurality of layers is deposited on a substrate in a first materials deposition chamber. The plurality of layers may include etch stop layers, release layers (i.e., layers designed to release the semiconductor layers from the substrate when a specific process sequence, such as chemical etching, is applied), contact layers such as lateral conduction layers, buffer layers, or other semiconductor layers. In one specific embodiment, the sequence of layers deposited is a buffer layer(s), then a release layer(s), and then a lateral conduction or contact layer(s). Next the substrate is transferred to a second materials deposition chamber where one or more subcells are deposited on top of the existing semiconductor layers. The substrate may then be transferred to either the first materials deposition chamber or to a third materials deposition chamber for deposition of one or more subcells and then deposition of one or more contact layers. Tunnel junctions are also formed between the subcells.

In certain embodiments provided by the present disclosure, the dilute nitride subcells are deposited in a first materials deposition chamber, and the (Al,In)GaP and (Al,In)GaAs subcells are deposited in a second materials deposition chamber, with tunnel junctions formed between the subcells. In another embodiment of the invention, a transfer occurs in the middle of the growth of one subcell, such that the said subcell has one or more layers deposited in one materials deposition chamber and one or more layers deposited in a second materials deposition chamber.

In certain embodiments provided by the present disclosure, some or all of the layers composing the dilute nitride subcells and the tunnel junctions are deposited in one materials deposition chamber by molecular beam epitaxy (MBE), and the remaining layers of the photovoltaic cell are deposited by chemical vapor deposition in another materials deposition chamber. For example, a substrate is placed in a first materials deposition chamber and layers that may include nucleation layers, buffer layers, emitter and window layers, contact layers and a tunnel junction are grown on the substrate using MBE, followed by one or more dilute nitride subcells grown using MBE. If there is more than one dilute nitride subcell, then a tunnel junction is grown between adjacent subcells. One or more tunnel junction layers may be grown, and then the substrate is transferred to a second materials deposition chamber where the remaining photovoltaic cell layers are grown by chemical vapor deposition. In certain embodiments, the chemical vapor deposition system is a MOCVD system. In a related embodiment, a substrate is placed in a first materials deposition chamber and layers that may include nucleation layers, buffer layers, emitter and window layers, contact layers and a tunnel junction are grown on the substrate by chemical vapor deposition. Subsequently, the top subcells, two or more, are grown on the existing semiconductor layers, with tunnel junctions grown between the subcells. Part of the topmost dilute nitride subcell, such as the window layer, may then be grown. The substrate is then transferred to a second materials deposition chamber where the remaining semiconductor layers of the topmost dilute nitride subcell may be grown using MBE, followed by up to three more dilute nitride subcells, with tunnel junctions between them using MBE.

Dilute nitride antimonides and dilute nitride bismides grown by MBE can have a hydrogen content of less than 1×10¹⁶ atoms/cm³, less than 5×10¹⁵ atoms/cm³, or less than 1×10¹⁵ atoms/cm³ as determined by secondary ion mass spectrometry (SIMS). In contrast, a dilute nitride antimonide and dilute nitride bismide grown by CVD can have a high hydrogen content which compromises the quality of dilute nitrides including dilute nitride bismides.

In certain embodiments provided by the present disclosure, the photovoltaic cell can be subjected to one or more thermal annealing treatments after growth. For example, a thermal annealing treatment can include exposure at a temperature of 400° C. to 1000° C. for between 10 seconds and 10 hours. Thermal annealing may be performed in an atmosphere that includes air, nitrogen, arsenic, arsine, phosphorus, phosphine, hydrogen, forming gas, oxygen, helium and any combination of the preceding materials. In certain embodiments, a stack of subcells and associated tunnel junctions may be annealed prior to fabrication of additional subcells.

It can be understood by those skilled in the art that a particular dilute nitride bismide composition does not inherently exhibit a particular band gap and a particular efficiency.

Various values for band gaps, short circuit current density Jsc and open circuit voltage Voc have been recited in the description and in the claims. It should be understood that these values are not exact. However, the values for band gaps can be approximated to one significant figure to the right of the decimal point, except where otherwise indicated. Thus, the value 0.9 covers the range 0.850 to 0.949. Also various numerical ranges have been recited in the description and in the claims. It should be understood that the numerical ranges are intended to include all sub-ranges encompassed by the range. For example, a range of “from 1 to 10” is intended to include all sub-ranges between and including the recited minimum value of 1 and the recited maximum value of 10, such as having a minimum value equal to or greater than 1 and a maximum value equal to or less than 10.

Bismuth-containing dilute nitrides such GaInNAsBi, GaInNAsBiSb, GaAsNBi, and GaAsNSbBi, can be used in semiconductor devices such as, for example, photovoltaic cells, multijunction photovoltaic cells, transistors, photodetectors, power converters, lasers, and optical amplifiers. As such, the present invention includes semiconductor devices incorporating a high quality bismuth-containing dilute nitride alloy provided the present disclosure, such as photovoltaic cells, multijunction photovoltaic cells, transistors, photodetectors, power converters, lasers, and optical amplifiers. Photovoltaic cells having one or more dilute nitride bismide subcells can be incorporated into a photovoltaic module and a photovoltaic system.

### Aspects of the Invention

Aspect 1. A multijunction photovoltaic cell comprising a dilute nitride bismide subcell, wherein the dilute nitride bismide subcell is characterized by, an efficiency of at least 70% at an irradiance energy from 1.38 eV to 1.30 eV, and an efficiency of at least 80% at an irradiance energy from 1.38 eV to 1.30 eV; an efficiency of at least 70% at an irradiance energy from 1.38 eV to 1.18 eV, and an efficiency of at least 80% at an irradiance energy from 1.38 eV to 1.30 eV; an efficiency of at least 70% at an irradiance energy from 1.38 eV to 1.10 eV, and an efficiency of at least 80% at an irradiance energy from 1.38 eV to 1.18 eV; an efficiency of at least 70% at an irradiance energy from 1.38 eV to 1.03 eV, and an efficiency of at least 80% at an irradiance energy from 1.38 eV to 1.15 eV; an efficiency of at least 70% at an irradiance energy from 1.38 eV to 0.99 eV, and an efficiency of at least 80% at an irradiance energy from 1.38 eV to 1.15 eV; or an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.15 eV; wherein the efficiency is measured at a junction temperature of 25° C.

Aspect 2. The multijunction photovoltaic cell of aspect 1, wherein the dilute nitride bismide subcell comprises Ga₁₋ₓInₓN_{y}As_{1-y-z}Bi_{z}, wherein the content values for x, y, and z are within composition ranges as follows: 0.03≦x≦0.19, 0.008≦y≦0.055, and 0.001≦z≦0.09.

Aspect 3. The multijunction photovoltaic cell of aspect 1, wherein the dilute nitride bismide subcell comprises Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09.

Aspect 4. The multijunction photovoltaic cell of aspect 1, wherein the dilute nitride bismide subcell comprises GaN_{y}As_{1-y-z}Bi_{z}, wherein the content values for y and z are within composition ranges as follows: 0.001≦y≦0.055, and 0.001≦z≦0.09.

Aspect 5. The multijunction photovoltaic cell of any one of aspects 1 to 4, wherein the dilute nitride bismide subcell comprises GaN_{y}As_{1-y-z1-z2}Sb_{z1}Bi_{z2}, wherein the content values for y and z are within composition ranges as follows: 0.001≦y≦0.055, and 0.001≦z1+z2≦0.09.

Aspect 6. The multijunction photovoltaic cell of any one of aspects 1 to 5, wherein the dilute nitride bismide subcell is characterized by a Eg/q-Voc equal to or greater than 0.55 V measured using a 1 sun AM1.5D spectrum at a junction temperature of 25° C.

Aspect 7. The multijunction photovoltaic cell of any one of aspects 1 to 6, wherein the dilute nitride bismide subcell is characterized by a Eg/q-Voc from 0.4 V to 0.7 V measured using a 1 sun AM1.5D spectrum at a junction temperature of 25° C.

Aspect 8. The multijunction photovoltaic cell of any one of aspects 1 to 7, wherein the dilute nitride bismide subcell is characterized by a bandgap within a range from 0.85 eV to 1.25 eV.

Aspect 9. The multijunction photovoltaic cell of any one of aspects 1 to 8, wherein the dilute nitride bismide subcell is substantially lattice-matched to a GaAs substrate or to a (Sn,Si)Ge substrate.

Aspect 10. The multijunction photovoltaic cell of any one of aspects 1 to 9, wherein the dilute nitride bismide subcell is p-doped or n-doped.

Aspect 11. The multijunction photovoltaic cell of any one of aspects 1 to 10, wherein the dilute nitride bismide subcell is characterized by a base thickness of 0.4 micron to 3.5 micron.

Aspect 12. The multijunction photovoltaic cell of any one of aspects 1 to 11, wherein the multijunction photovoltaic cell comprises at least three subcells.

Aspect 13. A photovoltaic module comprising at least one multijunction photovoltaic cell of any one of aspects 1 to 12.

Aspect 14. A photovoltaic system comprising at least one multijunction photovoltaic cell of any one of aspects 1 to 12.

Aspect 15. A dilute nitride bismide alloy comprising Ga₁₋ₓInₓN_{y}As_{1-y-z}Bi_{z}, wherein the content values for x, y, and z are within composition ranges as follows: 0.03≦x≦0.19, 0.008≦y≦0.055, and 0.001≦z≦0.09.

Aspect 16. A dilute nitride bismide alloy comprising Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09.

Aspect 17. A dilute nitride bismide alloy comprising GaN_{y}As_{1-y-z}Bi_{z}, wherein the content values for y and z are within composition ranges as follows: 0.001≦y≦0.055, and 0.001≦z≦0.09.

Aspect 18. A dilute nitride bismide alloy comprising GaN_{y}As_{1-y-z1-z2}Sb_{z1}Bi_{z2}, wherein the content values for y and z are within composition ranges as follows: 0.001≦y≦0.055, and 0.001≦z1+z2≦0.09.

Aspect 19. A semiconductor device comprising the dilute nitride bismide alloy of any one of aspects 15 to 18.

Aspect 20. The semiconductor device of aspect 19, wherein the semiconductor device comprises a photovoltaic cell, a multijunction photovoltaic cell, a laser, a photodiode, a transistor, a photodetector, a power converter, a laser, and an optical amplifier.

It should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

What is claimed is:

1. A multijunction photovoltaic cell comprising a dilute nitride bismide subcell, wherein, the dilute nitride bismide subcell comprises:
Ga₁ₓInₓN_{y}As_{1-y-z}Bi_{z}, wherein the content values for x, y, and z are within composition ranges as follows: 0.03≦x≦0.19, 0.008≦y≦0.055, and 0.001≦z≦0.09; Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09;
GaN_{y}As_{1-y-x}Bi_{z}, wherein the content values for y and z are within composition ranges as follows: 0.001≦y≦0.055, and 0.001≦z≦0.09; or
GaN_{y}As_{1-y-z1-z2}Sb_{z1}Bi_{z2}, wherein the content values for y and z are within composition ranges as follows: 0.001≦y≦0.055, and 0.001≦z1+z2≦0.09. and the dilute nitride bismide subcell is characterized by,
an efficiency of at least 70% at an irradiance energy from 1.38 eV to 1.30 eV, and an efficiency of at least 80% at an irradiance energy from 1.38 eV to 1.30 eV;
an efficiency of at least 70% at an irradiance energy from 1.38 eV to 1.18 eV, and an efficiency of at least 80% at an irradiance energy from 1.38 eV to 1.30 eV;
an efficiency of at least 70% at an irradiance energy from 1.38 eV to 1.10 eV, and an efficiency of at least 80% at an irradiance energy from 1.38 eV to 1.18 eV;
an efficiency of at least 70% at an irradiance energy from 1.38 eV to 1.03 eV, and an efficiency of at least 80% at an irradiance energy from 1.38 eV to 1.15 eV;
an efficiency of at least 70% at an irradiance energy from 1.38 eV to 0.99 eV, and an efficiency of at least 80% at an irradiance energy from 1.38 eV to 1.15 eV; or
an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.15 eV; wherein
the efficiency is measured at a junction temperature of 25° C.

2. The multijunction photovoltaic cell of claim 1, wherein the dilute nitride bismide subcell is characterized by a Eg/q-Voc equal to or greater than 0.55 V measured using a 1 sun AM1.5D spectrum at a junction temperature of 25° C.

3. The multijunction photovoltaic cell of claim 1, wherein the dilute nitride bismide subcell is characterized by a Eg/q-Voc from 0.4 V to 0.7 V measured using a 1 sun AM1.5D spectrum at a junction temperature of 25° C.

4. The multijunction photovoltaic cell of claim 1, wherein the dilute nitride bismide subcell is characterized by a bandgap within a range from 0.85 eV to 1.25 eV.

5. The multijunction photovoltaic cell of claim 1, wherein the dilute nitride bismide subcell is substantially lattice-matched to a GaAs substrate or to a (Sn,Si)Ge substrate.

6. The multijunction photovoltaic cell of claim 1, wherein the dilute nitride bismide subcell is p-doped or n-doped.

7. The multijunction photovoltaic cell of claim 1, wherein the dilute nitride bismide subcell is characterized by a base thickness of 0.4 micron to 3.5 micron.

8. The multijunction photovoltaic cell of claim 1, wherein the multijunction photovoltaic cell comprises at least three subcells.

9. A photovoltaic module comprising at least one multijunction photovoltaic cell of claim 1.

10. A photovoltaic system comprising at least one multijunction photovoltaic cell of claim 1.

11. A dilute nitride bismide alloy comprising Ga₁₋ₓInₓN_{y}As_{1-y-z}Bi_{z}, wherein the content values for x, y, and z are within composition ranges as follows: 0.03≦x≦0.19, 0.008≦y≦0.055, and 0.001≦z≦0.09.

12. A dilute nitride bismide alloy comprising Ga₁₋ₓInₓN_{y}As_{1-y-z1-z2}Sb_{z1}Bi_{z2}; wherein the content values for x, y, and z are within composition ranges as follows: 0.03≦x≦0.19, 0.008≦y≦0.055, and 0.001≦z1+z2≦0.09.

13. A dilute nitride bismide alloy comprising GaN_{y}As_{1-y-z}Bi_{z}, wherein the content values for y and z are within composition ranges as follows: 0.001≦y≦0.055, and 0.001≦z≦0.09.

14. A dilute nitride bismide alloy comprising GaN_{y}As_{1-y-z1-z2}Sb_{z1}Bi_{z2}, wherein the content values for y and z are within composition ranges as follows: 0.001≦y≦0.055, and 0.001≦z1+z2≦0.09.

15. A semiconductor device comprising the dilute nitride bismide alloy of claim 11.

16. The semiconductor device of claim 15, wherein the semiconductor device comprises a photovoltaic cell, a multijunction photovoltaic cell, a laser, a photodiode, a transistor, a photodetector, a power converter, a laser, and an optical amplifier.
